(19) United States
(12) Patent Application Publication
(10) Pub. No.: US 2026/0023102 A1
(43) Pub. Date: Jan. 22, 2026

(54) PACKAGED CHIP AND CURRENT SENSOR

(71) Applicant: NINGBO CRRC TIMES TRANSDUCER TECHNOLOGY CO., LTD, Ningbo (CN)

(72) Inventors: Yang LV, Ningbo (CN); Yanan SHI, Ningbo (CN); Xiaowei HOU, Ningbo (CN); Po ZHANG, Ningbo (CN); Mingming WU, Ningbo (CN)

(73) Assignee: NINGBO CRRC TIMES TRANSDUCER TECHNOLOGY CO., LTD, Ningbo (CN)

(21) Appl. No.: 19/339,075

(22) Filed: Sep. 24, 2025

Related U.S. Application Data
(63) Continuation of application No. PCT/CN2023/132872, filed on Nov. 21, 2023.

(30) Foreign Application Priority Data
Apr. 27, 2023 (CN) 202310465497.3

(51) Int. Cl. G01R 15/20

(52) U.S. Cl. CPC G01R 15/207

(57) ABSTRACT

A packaged chip and a current sensor, which are applied to the field of chip packaging. The packaged chip comprises: a substrate, a protective layer made of the same material as the substrate, and an active region prepared on one side surface of the substrate, wherein the side of the active region facing away from the substrate is bonded to the protective layer; and an isolation structure is formed between the protective layer and the substrate and on a side face of the active region. By means of the present application, the side, facing away from a substrate, of an active region prepared on the substrate is connected to a protective layer, and an isolation structure is formed between the protective layer and the substrate and on a side face of the active region, such that insulated isolation for the active region is formed.

### CROSS-REFERENCE TO RELATED APPLICATIONS

This present application claims priority to Chinese Patent Application No. 202310465497.3, filed with the China National Intellectual Property Administration on Apr. 27, 2023 and entitled “PACKAGED CHIP AND CURRENT SENSOR”, which is incorporated herein by reference in its entirety.

### TECHNICAL FIELD

The present application relates to the field of chip packaging, and in particular, to a packaged chip and a current sensor.

### BACKGROUND

To ensure the insulation performance of the devices, current sensors in the prior art generally adopt a wire bonding means, which requires adding insulating sheets on the back of the chips or adopting the SOI technique, and adopt a flip chip bonding means, which requires adding insulating sheets on the front of the chips. However, introducing external insulating materials may cause poor processing performance, low reliability, and other problems of the devices and lower the performance of the packaged chips and the overall current sensors.

### SUMMARY

In view of this, the present application aims to provide a packaged chip and a current sensor, solving the problem that introducing an external insulating material may cause poor processing performance, poor heat dissipation performance, low reliability, and other problems of a device and lower the performance of a packaged chip and an overall current sensor.

To solve the above technical problem, the present application provides a packaged chip, including:
a substrate, a protective layer made of the same material as the substrate, and an active region prepared on one side surface of the substrate, where
one side of the active region facing away from the substrate is bonded to the protective layer; and
an isolation structure is formed between the protective layer and the substrate and on a side face of the active region.

Optionally, a protruding bonding ball is disposed in the protective layer, one end of the protruding bonding ball is connected to the active region, and one end of the protruding bonding ball facing away from the active region extends out of the protective layer.

Optionally, a top heat dissipation component is disposed on one side of the substrate facing away from the active region.

Optionally, the top heat dissipation component is composed of an insulating film layer on one side in contact with the substrate and a metal heat dissipation layer on one side facing away from the substrate.

Optionally, the metal heat dissipation layer is disposed in an interdigital shape along a direction of the top heat dissipation component pointing to the substrate.

The present application further provides a current sensor, including:
the above packaged chip, an output lead-wire frame, a conductive lead-wire frame, and a bonding pad, wherein
the packaged chip is connected to a bonding joint in the output lead-wire frame;
the bonding pad is connected to the conductive lead-wire frame; and
the bonding pad forms a height difference with the packaged chip in a thickness direction of the bonding pad.

Optionally, a position in the bonding pad corresponding to the packaged chip is provided with an etching groove, to form the height difference with the packaged chip in the thickness direction of the bonding pad.

Optionally, a boundary of the etching groove extends out of a single side of the chip along a direction of the bonding pad pointing to the conductive lead-wire frame.

Optionally, the packaged chip is soldered to the bonding joint in the output lead-wire frame in a flip chip bonding manner.

Optionally, a packaged part of the output lead-wire frame and a packaged part of the conductive lead-wire frame are provided with etching grooves for preventing intrusion of impurities.

It can be seen that the packaged chip provided by the present application includes a substrate, a protective layer made of the same material as the substrate, and an active region prepared on one side surface of the substrate. One side of the active region facing away from the substrate is bonded to the protective layer; and an isolation structure is formed between the protective layer and the substrate and on the side face of the active region. By means of the present application, the side, facing away from a substrate, of an active region prepared on the substrate is connected to a protective layer, and an isolation structure is formed between the protective layer and the substrate and on a side face of the active region, such that insulated isolation for the active region is formed; when a formed chip structure is connected to other components, whether by using chip wire bonding, flip chip bonding, or other means, it is not necessary to additionally introduce an insulating material to the front or back of a chip; and in addition, by means of bonding the side of the active region facing away from the substrate to the protective layer, the use of dissimilar materials can be reduced, and the reliability of a device is improved while improving the insulation performance.

In addition, the present application further provides a current sensor, which also has the above beneficial effects.

### BRIEF DESCRIPTION OF THE DRAWINGS

To describe the technical solutions in the embodiments of the present application or in the prior art more clearly, the following briefly introduces the accompanying drawings required for describing the embodiments or the prior art. Apparently, the accompanying drawings in the following description are only the embodiments of the present application, and those of ordinary skill in the art may still derive other accompanying drawings from these accompanying drawings without creative efforts.

FIG. 1 is a schematic structural diagram of a packaged chip according to an embodiment of the present application;

FIG. 2 is a schematic structural diagram of another packaged chip according to an embodiment of the present application;

FIG. 3 is a schematic structural diagram of a metal heat dissipation layer in a top heat dissipation component according to an embodiment of the present application;

FIG. 4 is a schematic structural sectional view of a current sensor according to an embodiment of the present application;

FIG. 5 is a schematic structural sectional view of another current sensor according to an embodiment of the present application; and

FIG. 6 is a schematic structural top view of a current sensor according to an embodiment of the present application.

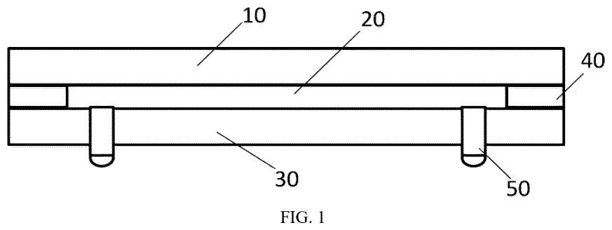

Reference numerals in FIG. 1 to FIG. 6 are as follows:
1. packaged chip;
10. substrate;
20. active region;
30. protective layer;
40. isolation structure;
50. protruding bonding ball;
60. top heat dissipation component, 61. metal heat dissipation layer, 62. insulating film layer;
71. output lead-wire frame, 72. conductive lead-wire frame, 73. bonding pad, 74, etching groove;
80. packaged region.

### DETAILED DESCRIPTION OF THE EMBODIMENTS

To make the objectives, technical solutions, and advantages of the embodiments of the present application clearer, the following clearly and completely describes the technical solutions in the embodiments of the present application with reference to the accompanying drawings in the embodiments of the present application. Apparently, the described embodiments are only some but not all of the embodiments of the present application. All other embodiments obtained by those of ordinary skill in the art based on the embodiments of the present application without creative efforts shall fall within the protection scope of the present application.

An example of SOI (silicon on insulator) is described. An existing current sensor generally prepares a chip by using a single SOI substrate means. When the chip is connected to a lead-wire frame by using a flip chip bonding means, it is often necessary to additionally introduce an insulating material between the chip and the lead-wire frame, to ensure the insulation performance of a device. Generally, an insulating sheet is added between the chip and a bonding pad of the lead-wire frame. However, introducing an external insulating sheet increases a risk of delamination between different materials, resulting in poor processing performance, low reliability, and other problems of the device, thereby reducing the performance of the packaged chip and the overall current sensor.

By means of the present application, the side, facing away from a substrate, of an active region prepared on the substrate is connected to a protective layer, and an isolation structure is formed between the protective layer and the substrate and on a side face of the active region, such that insulated isolation for the active region is formed; when a formed chip structure is connected to other components, whether by using chip wire bonding, flip chip bonding, or other means, it is not necessary to additionally introduce an insulating material to the front or back of a chip; and in addition, by means of bonding the side of the active region facing away from the substrate to the protective layer, the use of dissimilar materials can be reduced, and the reliability of a device is improved while improving the insulation performance.

### Embodiment 1

Referring to FIG. 1, FIG. 1 is a schematic structural diagram of a packaged chip according to an embodiment of the present application. The packaged chip may include:
a substrate 10, a protective layer 30 made of the same material as the substrate 10, and an active region 20 prepared on one side surface of the substrate 10, where
one side of the active region 20 facing away from the substrate 10 is bonded to the protective layer 30; and
an isolation structure 40 is formed between the protective layer 30 and the substrate 10 and on a side face of the active region 20.

It needs to be noted that the substrate 10, the protective layer 30, and the isolation structure 40 in this embodiment cover the active region 20 in a formed enclosed space. A specific material of the substrate 10 is not limited in this embodiment. For example, the substrate 10 may be a silicon-based substrate 10, or the substrate 10 may be an aluminum oxide substrate 10, or the substrate 10 may also be a substrate 10 made of other materials. Regardless of the material of the substrate 10, the material of the protective layer 30 is the same as that of the substrate 10. In this embodiment, the side of the active region 20 facing away from the substrate 10 is bonded to the protective layer 30, and when a prepared chip is connected to the outside, it is not necessary to additionally introduce an insulating medium, thereby avoiding a problem of delamination between different materials during combination and improving the reliability of a device. It needs to be further noted that in this embodiment, to ensure the airtightness and insulativity of the prepared chip, the isolation structure 40 is formed between the above protective layer 30 and substrate 10. A material of the isolation structure 40 may be the same as that of the substrate 10.

Correspondingly, a specific type of the active region 20 prepared on one side surface of the substrate 10 is not limited in this embodiment. For example, a Hall current chip may be disposed in the active region 20, or other types of chips may also be disposed in the active region 20. A specific type of the isolation structure 40 formed on the side face of the active region 20 is not limited in this embodiment. For example, the isolation structure 40 may be a DTI (deep trench isolation) technology, or the isolation structure 40 may be STI (shallow trench isolation). It may be predicted that the deep trench isolation technology adopted in this embodiment has better insulativity and airtightness effects for the active region 20.

The packaged chip, including the substrate 10, the protective layer 30 made of the same material as the substrate 10, and the active region 20 prepared on one side surface of the substrate 10, provided by the present application is applied. The side of the active region 20 facing away from the substrate 10 is bonded to the protective layer 30; and the isolation structure 40 is formed between the protective layer 30 and the substrate 10 and on the side face of the active region 20. By means of the present application, the side, facing away from the substrate 10, of the active region 20 prepared on the substrate 10 is connected to the protective layer 30, and the isolation structure 40 is formed between the protective layer 30 and the substrate 10 and on the side face of the active region 20, such that insulated isolation for the active region 20 is formed; when a formed chip structure is connected to other components, whether by using chip wire bonding, flip chip bonding, or other means, it is not necessary to additionally introduce an insulating material to the front or back of a chip; and in addition, by means of bonding the side of the active region 20 facing away from the substrate 10 to the protective layer 30, the use of dissimilar materials can be reduced, and the reliability of a device is improved while improving the insulation performance, thereby avoiding a phenomenon of delamination during packaging.

### Embodiment 2

Referring to FIG. 1, FIG. 1 is a schematic structural diagram of a packaged chip according to an embodiment of the present application. The packaged chip may include:
a substrate 10, a protective layer 30 made of the same material as the substrate 10, and an active region 20 prepared on one side surface of the substrate 10, where
one side of the active region 20 facing away from the substrate 10 is bonded to the protective layer 30;
an isolation structure 40 is formed between the protective layer 30 and the substrate 10 and on a side face of the active region 20; and
a protruding bonding ball 50 is disposed in the protective layer 30, one end of the protruding bonding ball 50 is connected to the active region 20, and one end of the protruding bonding ball 50 facing away from the active region 20 extends out of the protective layer 30.

It needs to be noted that in this embodiment, the active region 20 is connected to one end of the protruding bonding ball 50 in the protective layer 30, and the other end of the protruding bonding ball 50 extends out of the protective layer 30, so that the active region 20 can be electrically connected to the outside. In this embodiment, there may be two protruding bonding balls 50, which correspond to positive and negative electrodes of the active region 20 respectively. However, according to a type of the active region 20, a number of the protruding bonding balls 50 may be adjusted, that is, the number of the protruding bonding balls 50 disposed in the protective layer 30 is not limited in this embodiment.

The packaged chip, including the substrate 10, the protective layer 30 made of the same material as the substrate 10, and the active region 20 prepared on one side surface of the substrate 10, provided by the present application is applied. The side of the active region 20 facing away from the substrate 10 is bonded to the protective layer 30; and the isolation structure 40 is formed between the protective layer 30 and the substrate 10 and on the side face of the active region 20. By means of the present application, the side, facing away from the substrate 10, of the active region 20 prepared on the substrate 10 is connected to the protective layer 30, and the isolation structure 40 is formed between the protective layer 30 and the substrate 10 and on the side face of the active region 20, such that insulated isolation for the active region 20 is formed; when a formed chip structure is connected to other components, whether by using chip wire bonding, flip chip bonding, or other means, it is not necessary to additionally introduce an insulating material to the front or back of a chip; and in addition, by means of bonding the side of the active region 20 facing away from the substrate 10 to the protective layer 30, the use of dissimilar materials can be reduced, and the reliability of a device is improved while improving the insulation performance. By means of disposing the protruding bonding ball 50 in the protective layer 30, connecting one end of the protruding bonding ball 50 to the active region 20, and extending one end of the protruding bonding ball 50 facing away from the active region 20 out of the protective layer 30, on the premise of ensuring insulated sealing of the active region 20, the active region can be electrically connected to the outside, thereby avoiding a phenomenon of delamination during packaging.

### Embodiment 3

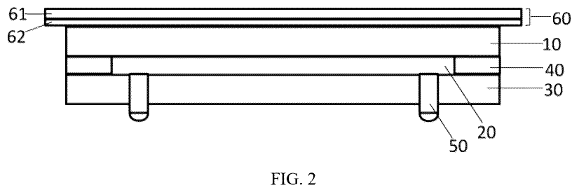

Referring to FIG. 2, FIG. 2 is a schematic structural diagram of another packaged chip according to an embodiment of the present application. The packaged chip may include:
a substrate 10, a protective layer 30 made of the same material as the substrate 10, and an active region 20 prepared on one side surface of the substrate 10, where
one side of the active region 20 facing away from the substrate 10 is bonded to the protective layer 30;
an isolation structure 40 is formed between the protective layer 30 and the substrate 10 and on a side face of the active region 20; and
a top heat dissipation component 60 is disposed on one side of the substrate 10 facing away from the active region 20.

It needs to be noted that to ensure the insulativity of the prepared packaged chip, a lead-wire frame and a bonding pad need to be minimized as much as possible, and a heat dissipation property of the chip is reduced at the same time. Therefore, to avoid the reduction of the heat dissipation performance of the chip, the top heat dissipation component 60 is disposed on one side of the above substrate 10 facing away from the active region 20.

In this embodiment, the top heat dissipation component 60 is disposed on one side of the substrate 10 facing away from the active region 20, so that heat can be effectively dissipated from the chip. A specific type of the top heat dissipation component 60 is not limited in this embodiment as long as heat dissipation can be performed on the chip. For example, the top heat dissipation component 60 may be made of a metal material, or the top heat dissipation component 60 may also be made of a ceramic material, or the top heat dissipation component 60 may further be made of other materials or a combination of a plurality of materials. A specific shape of the top heat dissipation component 60 is not limited in this embodiment. For example, the top heat dissipation component 60 may be of a disc structure, or the top heat dissipation component 60 may also be of a rectangular shape, or the top heat dissipation component 60 may further be of other shapes or a combination of a plurality of shapes. A specific structure of the top heat dissipation component 60 is not limited in this embodiment. For example, the top heat dissipation component 60 may be of a platelike structure; or the top heat dissipation component 60 may further be of a platelike structure with a hollowed-out structure in the middle; or the top heat dissipation component 60 may also be of a structure with an edge extending downwards to wrap a part of a side wall of the chip; or the top heat dissipation component 60 may further be of other structures that can improve the heat dissipation performance.

Further, to ensure the insulativity of the top heat dissipation component 60 and the chip while ensuring the heat dissipation performance of the top heat dissipation component 60, the above top heat dissipation component 60 may be composed of an insulating film layer 62 on one side in contact with the substrate 10 and a metal heat dissipation layer 61 on one side facing away from the substrate 10.

It should be noted that the top heat dissipation component 60 is composed of the metal heat dissipation layer 61 on one side facing away from the substrate 10 and the insulating film layer 62 on one side in contact with the substrate 10, so that the metal heat dissipation layer 61 can be used to dissipate heat from the chip, and the insulating film layer 62 can be used to improve the insulativity of the chip, thereby further improving the stability of the packaged chip.

A specific material of the insulating film layer 62 is not limited in this embodiment as long as an insulating effect can be achieved. For example, the insulating film layer 62 may be made of a ceramic material, or the insulating film layer 62 may also be made of an organic insulating film material such as a polyimide material, or the insulating film layer 62 may further be made of other insulating materials.

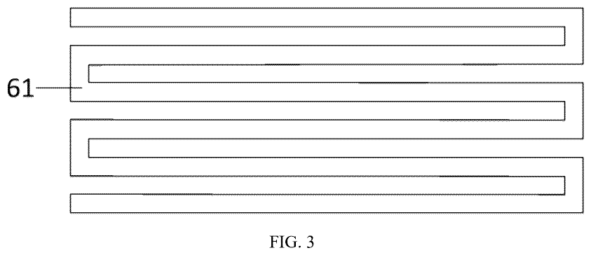

Further, to further improve the heat dissipation performance of the metal heat dissipation layer 61, the above metal heat dissipation layer 61 may be disposed in an interdigital shape along a direction of the top heat dissipation component 60 pointing to the substrate 10. Specifically, referring to FIG. 3, FIG. 3 is a schematic structural diagram of the metal heat dissipation layer 61 in the top heat dissipation component 60 according to an embodiment of the present application.

It needs to be noted that in this embodiment, the metal heat dissipation layer 61 is disposed in the interdigital shape along the direction of the top heat dissipation component 60 pointing to the substrate 10, so that a heat dissipation area of the metal heat dissipation layer 61 can be increased, thereby improving the heat dissipation performance of the metal heat dissipation layer 61.

A specific number of layers of the metal heat dissipation layer 61 disposed in the interdigital shape is not limited in this embodiment. For example, there may be 5 layers of the metal heat dissipation layer 61 disposed in the interdigital shape, or there may also be 8 layers of the metal heat dissipation layer 61 disposed in the interdigital shape, or there may further be 10 layers of the metal heat dissipation layer 61 disposed in the interdigital shape. It may be expected that the more the number of layers of the metal heat dissipation layer 61 disposed in the interdigital shape, the better the heat dissipation effect of the metal heat dissipation layer 61. Correspondingly, a specific distance between different layers in the metal heat dissipation layer 61 is not limited in this embodiment.

The packaged chip, including the substrate 10, the protective layer 30 made of the same material as the substrate 10, and the active region 20 prepared on one side surface of the substrate 10, provided by the present application is applied. The side of the active region 20 facing away from the substrate 10 is bonded to the protective layer 30; and the isolation structure 40 is formed between the protective layer 30 and the substrate 10 and on the side face of the active region 20. By means of the present application, the side, facing away from the substrate 10, of the active region 20 prepared on the substrate 10 is connected to the protective layer 30, and the isolation structure 40 is formed between the protective layer 30 and the substrate 10 and on the side face of the active region 20, such that insulated isolation for the active region 20 is formed; when a formed chip structure is connected to other components, whether by using chip wire bonding, flip chip bonding, or other means, it is not necessary to additionally introduce an insulating material to the front or back of a chip; and in addition, by means of bonding the side of the active region 20 facing away from the substrate 10 to the protective layer 30, the use of dissimilar materials can be reduced, and the reliability of a device is improved while improving the insulation performance. By means of disposing the top heat dissipation component 60 on one side of the substrate 10 facing away from the active region 20, the heat can be effectively dissipated from the chip, thereby avoiding a phenomenon of delamination during packaging. In addition, in the present application, the top heat dissipation component 60 is composed of the insulating film layer 62 on one side in contact with the substrate 10 and the metal heat dissipation layer 61 on one side facing away from the substrate 10, so that the insulativity of the top heat dissipation component 60 and the chip can be ensured while ensuring the heat dissipation performance of the top heat dissipation component 60. The metal heat dissipation layer 61 is disposed in the interdigital shape along the direction of the top heat dissipation component 60 pointing to the substrate 10, thereby further improving the heat dissipation performance of the metal heat dissipation layer 61.

The following introduces a current sensor provided by an embodiment of the present application, and the current sensor described below and the packaged chip described above may refer to each other.

### Embodiment 4

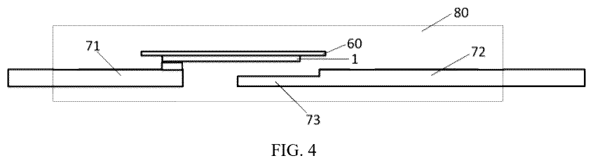

Specifically, referring to FIG. 4, FIG. 4 is a schematic structural sectional view of a current sensor according to an embodiment of the present application, which may include:
a packaged chip 1, an output lead-wire frame 71, a conductive lead-wire frame 72, and a bonding pad 73, where
the packaged chip 1 is connected to a bonding joint in the output lead-wire frame 71;
the bonding pad 73 is connected to the conductive lead-wire frame 72; and
the bonding pad 73 forms a height difference with the packaged chip 1 in a thickness direction of the bonding pad 73.

It needs to be noted that the packaged chip 1 in this embodiment includes the structure in any one of the above embodiments. In this embodiment, the current sensor is described by taking an open loop Hall current sensor as an example, and the bonding pad 73 connected to the wire lead-wire frame forms the height difference with the packaged chip 1 in the thickness direction.

A specific connection means between the packaged chip 1 and the bonding joint in the output lead-wire frame 71 is not limited in this embodiment. For example, the packaged chip 1 may be connected to the bonding joint in the output lead-wire frame 71 through a lead wire, or the packaged chip 1 may also be directly bonded to the bonding joint in the output lead-wire frame 71. A specific means of the bonding pad 73 forming the height difference with the packaged chip 1 in the thickness direction of the bonding pad 73 is not limited in this embodiment. For example, the conductive lead-wire frame 72 and the output lead-wire frame 71 may be disposed at different heights, or the bonding pad 73 may also form the height difference with the packaged chip 1 in the thickness direction of the bonding pad 73 in other means.

Further, to ensure a sealing property of the current sensor, considering a use scenario of the current sensor, a package body may be used to package the packaged chip 1, a packaged part of the output lead-wire frame 71, a packaged part of the conductive lead-wire frame 72, and the bonding pad 73. A packaged region 80 in FIG. 4 is a packaged region of the current sensor, including the above packaged chip 1, the packaged part of the output lead-wire frame 71, the packaged part of the conductive lead-wire frame 72, and the bonding pad 73.

A specific composition material of the package body is not limited in this embodiment. For example, the package body may be made of a molding material, or the package body may also be made of a silicone gel material, or the package body may also be made of other insulating materials.

The current sensor, including the packaged chip 1, the output lead-wire frame 71, the conductive lead-wire frame 72, and the bonding pad 73, provided by the present application is applied. The packaged chip 1 is connected to the bonding joint in the output lead-wire frame 71, the bonding pad 73 is connected to the conductive lead-wire frame 72, and the bonding pad 73 forms the height difference with the packaged chip 1 in the thickness direction of the bonding pad 73. The packaged chip 1 includes a substrate, a protective layer made of the same material as the substrate, and an active region prepared on one side surface of the substrate. One side of the active region facing away from the substrate is bonded to the protective layer; and an isolation structure is formed between the protective layer and the substrate and on the side face of the active region. By means of the present application, the side, facing away from the substrate, of the active region prepared on the substrate is connected to the protective layer, and the isolation structure is formed between the protective layer and the substrate and on the side face of the active region, such that insulated isolation for the active region is formed; when a formed chip structure is connected to other components, whether by using chip wire bonding, flip chip bonding, or other means, it is not necessary to additionally introduce an insulating material to the front or back of a chip; and in addition, by means of bonding the side of the active region facing away from the substrate to the protective layer, the use of dissimilar materials can be reduced, and the reliability of a device is improved while improving the insulation performance, thereby avoiding a phenomenon of delamination during packaging. When connecting to an external lead-wire frame, it is not necessary to introduce an organic gasket material, thereby improving the preparation efficiency.

### Embodiment 5

Specifically, referring to FIG. 4, FIG. 4 is a schematic structural sectional view of a current sensor according to an embodiment of the present application, which may include:
a packaged chip 1, an output lead-wire frame 71, a conductive lead-wire frame 72, and a bonding pad 73, where
the packaged chip 1 is connected to a bonding joint in the output lead-wire frame 71;
the bonding pad 73 is connected to the conductive lead-wire frame 72;
the bonding pad 73 forms a height difference with the packaged chip 1 in a thickness direction of the bonding pad 73; and
a position in the bonding pad 73 corresponding to the packaged chip 1 is provided with an etching groove, to form the height difference with the packaged chip 1 in the thickness direction of the bonding pad 73.

It needs to be noted that in this embodiment, the position in the bonding pad 73 corresponding to the packaged chip 1 is provided with the etching groove, so that the bonding pad 73 forms the height difference with the packaged chip 1 in the thickness direction and is filled with a package material after being packaged, which can increase an actual working creepage distance. A specific depth of the etching groove formed in the bonding pad 73 is not limited in this embodiment, which may be set by an operator in a customized manner.

Further, to ensure that there are height differences between the bonding pad 73 and the packaged chip 1 along various directions at the edge, and a boundary of the above etching groove extends out of a single side of the chip along a direction of the bonding pad 73 pointing to the conductive lead-wire frame 72.

It needs to be noted that in this embodiment, the boundary of the etching groove extends out of the single side of the chip along the direction of the bonding pad 73 pointing to the conductive lead-wire frame 72, so that the packaged chip 1 can still maintain the height difference with the boundary of the etching groove in the bonding pad 73 at the edge along the direction of the bonding pad 73 pointing to the conductive lead-wire frame 72. A specific value of the boundary of the etching groove extending out of the single side of the chip along the direction of the bonding pad 73 pointing to the conductive lead-wire frame 72 is not limited in this embodiment as long as the creepage distance between the packaged chip 1 and the bonding pad 73 is met, which may be set by the operator in a customized manner.

The current sensor, including the packaged chip 1, the output lead-wire frame 71, the conductive lead-wire frame 72, and the bonding pad 73, provided by the present application is applied. The packaged chip 1 is connected to the bonding joint in the output lead-wire frame 71, the bonding pad 73 is connected to the conductive lead-wire frame 72, and the bonding pad 73 forms the height difference with the packaged chip 1 in the thickness direction of the bonding pad 73. The packaged chip 1 includes a substrate, a protective layer made of the same material as the substrate, and an active region prepared on one side surface of the substrate. One side of the active region facing away from the substrate is bonded to the protective layer; and an isolation structure is formed between the protective layer and the substrate and on the side face of the active region. By means of the present application, the side, facing away from the substrate, of the active region prepared on the substrate is connected to the protective layer, and the isolation structure is formed between the protective layer and the substrate and on the side face of the active region, such that insulated isolation for the active region is formed; when a formed chip structure is connected to other components, whether by using chip wire bonding, flip chip bonding, or other means, it is not necessary to additionally introduce an insulating material to the front or back of a chip; and in addition, by means of bonding the side of the active region facing away from the substrate to the protective layer, the use of dissimilar materials can be reduced, and the reliability of a device is improved while improving the insulation performance. By means of forming the etching groove at the position in the bonding pad 73 corresponding to the packaged chip 1 to form the height difference between the bonding pad 73 and the packaged chip 1, the actual working creepage distance can be increased more conveniently, and the complexity of the preparation of the sensor is reduced, thereby avoiding a phenomenon of delamination during packaging. When connecting to an external lead-wire frame, it is not necessary to introduce an organic gasket material, thereby improving the preparation efficiency. In addition, the boundary of the etching groove extends out of the single side of the chip along the direction of the bonding pad 73 pointing to the conductive lead-wire frame 72, so that it can be ensured that there are the height differences between the bonding pad 73 and the packaged chip 1 along various directions at the edge.

### Embodiment 6

Specifically, referring to FIG. 4, FIG. 4 is a schematic structural sectional view of a current sensor according to an embodiment of the present application, which may include:
a packaged chip 1, an output lead-wire frame 71, a conductive lead-wire frame 72, and a bonding pad 73, where
the packaged chip 1 is connected to a bonding joint in the output lead-wire frame 71;
the bonding pad 73 is connected to the conductive lead-wire frame 72;
the bonding pad 73 forms a height difference with the packaged chip 1 in a thickness direction of the bonding pad 73; and
the packaged chip 1 is soldered to the bonding joint in the output lead-wire frame 71 in a flip chip bonding manner.

It needs to be noted that in this embodiment, a protruding bonding ball in the packaged chip 1 may be soldered to the bonding joint in the output lead-wire frame 71, so that an active region in the packaged chip 1 is electrically connected to the bonding joint in the output lead-wire frame 71.

The current sensor, including the packaged chip 1, the output lead-wire frame 71, the conductive lead-wire frame 72, and the bonding pad 73, provided by the present application is applied. The packaged chip 1 is connected to the bonding joint in the output lead-wire frame 71, the bonding pad 73 is connected to the conductive lead-wire frame 72, and the bonding pad 73 forms the height difference with the packaged chip 1 in the thickness direction of the bonding pad 73. The packaged chip 1 includes a substrate, a protective layer made of the same material as the substrate, and an active region prepared on one side surface of the substrate. One side of the active region facing away from the substrate is bonded to the protective layer; and an isolation structure is formed between the protective layer and the substrate and on the side face of the active region. By means of the present application, the side, facing away from the substrate, of the active region prepared on the substrate is connected to the protective layer, and the isolation structure is formed between the protective layer and the substrate and on the side face of the active region, such that insulated isolation for the active region is formed; when a formed chip structure is connected to other components, whether by using chip wire bonding, flip chip bonding, or other means, it is not necessary to additionally introduce an insulating material to the front or back of a chip; and in addition, by means of bonding the side of the active region facing away from the substrate to the protective layer, the use of dissimilar materials can be reduced, and the reliability of a device is improved while improving the insulation performance. By means of soldering the protruding bonding ball in the packaged chip 1 to the bonding joint in the output lead-wire frame 71, the stability of connection between the packaged chip 1 and the output lead-wire frame 71 is improved while avoiding the additional introduction of a connecting material, thereby avoiding a phenomenon of delamination during packaging. When connecting to an external lead-wire frame, it is not necessary to introduce an organic gasket material, thereby improving the preparation efficiency.

### Embodiment 7

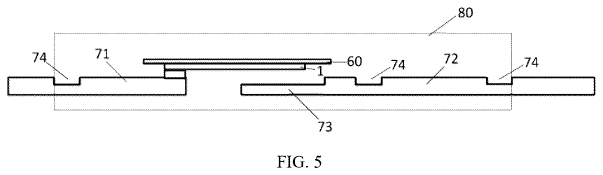

Specifically, referring to FIG. 5, FIG. 5 is a schematic structural sectional view of another current sensor according to an embodiment of the present application, which may include:
a packaged chip 1, an output lead-wire frame 71, a conductive lead-wire frame 72, and a bonding pad 73, where
the packaged chip 1 is connected to a bonding joint in the output lead-wire frame 71;
the bonding pad 73 is connected to the conductive lead-wire frame 72;
the bonding pad 73 forms a height difference with the packaged chip 1 in a thickness direction of the bonding pad 73; and
a packaged part of the output lead-wire frame 71 and a packaged part of the conductive lead-wire frame 72 are provided with etching grooves 74 for preventing the intrusion of impurities.

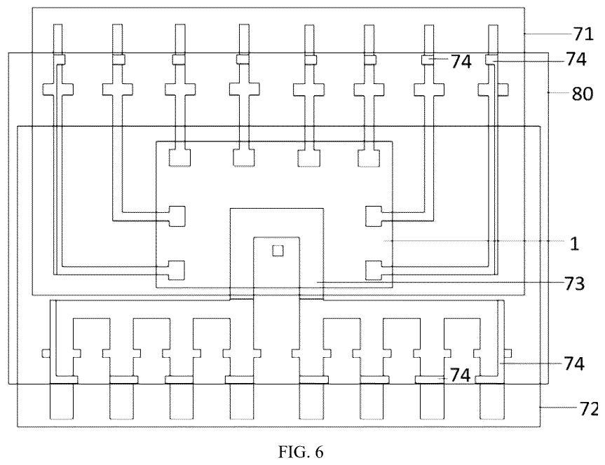

It needs to be noted that when the packaged chip 1, the packaged part of the output lead-wire frame 71, the packaged part of the conductive lead-wire frame 72, and the bonding pad 73 are packaged, external impurities intrude into the package along an interface formed between the conductive lead-wire frame 72 and a package body or along an interface formed between the output lead-wire frame 71 and a package body, to damage the sensor. In this embodiment, the packaged part of the output lead-wire frame 71 and the packaged part of the conductive lead-wire frame 72 are provided with the etching grooves 74, so that the intrusion of impurities can be prevented after the package body is used for packaging, thereby improving the reliability of the sensor. The current sensor provided by this embodiment may specifically refer to FIG. 6, and FIG. 6 is a schematic structural top view of a current sensor according to an embodiment of the present application.

A number of the formed etching grooves 74 is not limited in this embodiment. For example, there may be 1 etching groove 74, or there may also be 2 etching grooves 74, or there may further be 3 etching grooves 74. A specific shape of the formed etching groove 74 is not limited in this embodiment. For example, the shape of the etching groove 74 may be a cylindrical shape, or the shape of the etching groove 74 may also be a rectangular shape, or the shape of the etching groove 74 may further be other shapes and a combination of any shapes. A depth of the etching groove 74 is not limited in this embodiment, which may be adjusted and set by an operator.

The current sensor, including the packaged chip 1, the output lead-wire frame 71, the conductive lead-wire frame 72, and the bonding pad 73, provided by the present application is applied. The packaged chip 1 is connected to the bonding joint in the output lead-wire frame 71, the bonding pad 73 is connected to the conductive lead-wire frame 72, and the bonding pad 73 forms the height difference with the packaged chip 1 in the thickness direction of the bonding pad 73. The packaged chip 1 includes a substrate, a protective layer made of the same material as the substrate, and an active region prepared on one side surface of the substrate. One side of the active region facing away from the substrate is bonded to the protective layer; and an isolation structure is formed between the protective layer and the substrate and on the side face of the active region. By means of the present application, the side, facing away from the substrate, of the active region prepared on the substrate is connected to the protective layer, and the isolation structure is formed between the protective layer and the substrate and on the side face of the active region, such that insulated isolation for the active region is formed; when a formed chip structure is connected to other components, whether by using chip wire bonding, flip chip bonding, or other means, it is not necessary to additionally introduce an insulating material to the front or back of a chip; and in addition, by means of bonding the side of the active region facing away from the substrate to the protective layer, the use of dissimilar materials can be reduced, and the reliability of a device is improved while improving the insulation performance. By means of forming the etching grooves 74 on the packaged part of the output lead-wire frame 71 and the packaged part of the conductive lead-wire frame 72, external impurities can be effectively prevented from intruding into the sensor, thereby avoiding a phenomenon of delamination during packaging. When connecting to an external lead-wire frame, it is not necessary to introduce an organic gasket material, thereby improving the preparation efficiency.

For ease of easier understanding of the present application, the current sensor provided by the present application may specifically include:
a packaged chip 1, an output lead-wire frame 71, a conductive lead-wire frame 72, and a bonding pad 73, where
the packaged chip 1 includes a substrate 10, a protective layer 30 made of the same material as the substrate 10, and an active region 20 prepared on one side surface of the substrate 10; one side of the active region 20 facing away from the substrate 10 is bonded to the protective layer 30; and an isolation structure 40 is formed between the protective layer 30 and the substrate 10 and on the side face of the active region 20;
a protruding bonding ball 50 is disposed in the protective layer 30, one end of the protruding bonding ball 50 is connected to the active region 20, and one end of the protruding bonding ball 50 facing away from the active region 20 extends out of the protective layer 30;
a top heat dissipation component 60 is disposed on one side of the substrate 10 facing away from the active region 20; the top heat dissipation component 60 is composed of an insulating film layer 62 on one side in contact with the substrate 10 and a metal heat dissipation layer 61 on one side facing away from the substrate 10; and the metal heat dissipation layer 61 is disposed in an interdigital shape along a direction of the top heat dissipation component 60 pointing to the substrate 10;
the packaged chip 1 is connected to a bonding joint in the output lead-wire frame 71; the bonding pad 73 is connected to the conductive lead-wire frame 72; a position in the bonding pad 73 corresponding to the packaged chip 1 is provided with an etching groove, to form a height difference with the packaged chip 1 in a thickness direction of the bonding pad 73; and a boundary of the etching groove extends out of a single side of the chip along a direction of the bonding pad 73 pointing to the conductive lead-wire frame 72;
the packaged chip 1 is soldered to the bonding joint in the output lead-wire frame 71 through a protruding bonding ball 50 in a flip chip bonding manner; and
a packaged part of the output lead-wire frame 71 and a packaged part of the conductive lead-wire frame 72 are provided with etching grooves 74 for preventing the intrusion of impurities.

Various embodiments in the specification are described in a progressive manner, and each embodiment focuses on the differences from the other embodiments, and the same or similar parts between the various embodiments can refer to each other.

Finally, it needs to further be noted that relational terms herein, such as first and second, are only used to distinguish one entity or operation from another entity or operation, and do not necessarily require or imply any such actual relationship or order among these entities or operations. In addition, the terms “include”, “comprise”, or any other variants thereof are intended to cover non-exclusive inclusion.

The packaged chip and the current sensor provided by the present application are described above in detail. The present application is elaborated by applying a plurality of specific examples. The descriptions of the above embodiments are only used to help understand the method and its core idea of the present application; meanwhile, according to the idea of the present application, there will be changes in the specific implementations and the application scope for those of ordinary skill in the art. In summary, the content of the specification should not be understood as a limitation to the present application.

What is claimed is:

1. A packaged chip, comprising:
a substrate, a protective layer made of the same material as the substrate, and an active region prepared on one side surface of the substrate, wherein
one side of the active region facing away from the substrate is bonded to the protective layer; and
a deep trench isolation structure made of the same material as the substrate is formed between the protective layer and the substrate and on a side face of the active region, to enable the substrate, the protective layer, and the deep trench isolation structure to cover the active region in a sealing manner.

2. The packaged chip according to claim 1, wherein a protruding bonding ball is disposed in the protective layer, one end of the protruding bonding ball is connected to the active region, and one end of the protruding bonding ball facing away from the active region extends out of the protective layer.

3. The packaged chip according to claim 1, wherein a top heat dissipation component is disposed on one side of the substrate facing away from the active region.

4. The packaged chip according to claim 3, wherein the top heat dissipation component is composed of an insulating film layer on one side in contact with the substrate and a metal heat dissipation layer on one side facing away from the substrate.

5. The packaged chip according to claim 4, wherein the metal heat dissipation layer is disposed in an interdigital shape along a direction of the top heat dissipation component pointing to the substrate.

6. A current sensor, comprising:
the packaged chip according to claim 1, an output lead-wire frame, a conductive lead-wire frame, and a bonding pad, wherein
the packaged chip is connected to a bonding joint in the output lead-wire frame;
the bonding pad is connected to the conductive lead-wire frame; and
the bonding pad forms a height difference with the packaged chip in a thickness direction of the bonding pad.

7. The current sensor according to claim 6, wherein a position in the bonding pad corresponding to the packaged chip is provided with an etching groove, to form the height difference with the packaged chip in the thickness direction of the bonding pad.

8. The current sensor according to claim 7, wherein a boundary of the etching groove extends out of a single side of the chip along a direction of the bonding pad pointing to the conductive lead-wire frame.

9. The current sensor according to claim 6, wherein the packaged chip is soldered to the bonding joint in the output lead-wire frame in a flip chip bonding manner.

10. The current sensor according to claim 6, wherein a packaged part of the output lead-wire frame and a packaged part of the conductive lead-wire frame are provided with etching grooves for preventing intrusion of impurities.
